(19) United States
(12) Patent Application Publication
(10) Pub. No.: US 2026/0190417 A1
(43) Pub. Date: Jul. 2, 2026

(54) SEMICONDUCTOR DEVICE INCLUDING DEEP METAL CONTACT AND METHOD FOR MANUFACTURING THE SAME

(71) Applicant: TAIWAN SEMICONDUCTOR MANUFACTURING COMPANY, LTD., Hsinchu (TW)

(72) Inventors: Ta-Chun LIN, Hsinchu (TW); Jhon Jhy LIAW, Hsinchu (TW)

(73) Assignee: TAIWAN SEMICONDUCTOR MANUFACTURING COMPANY, LTD., Hsinchu (TW)

(21) Appl. No.: 19/002,351

(22) Filed: Dec. 26, 2024

(51) Int. Cl. H10D 64/23; H10D 30/00; H10D 30/01; H10D 30/40; H10D 62/10; H10D 62/13

(52) U.S. Cl. CPC H10D 64/251; H10D 30/014; H10D 30/019; H10D 30/40; H10D 30/501; H10D 62/121; H10D 62/151

(57) ABSTRACT

A method for manufacturing a semiconductor device includes: forming a first semiconductor assembly and a second semiconductor assembly on a semiconductor substrate, each of the first and second semiconductor assemblies including a pair of source/drain portions; forming a mask layer to selectively cover the source/drain portions of the second semiconductor assembly, so as to expose the source/drain portions of the first semiconductor assembly; removing a part of each of the source/drain portions of the first semiconductor assembly; removing the mask layer to expose the source/drain portions of the second semiconductor assembly; and forming a first metal contact feature on a remaining part of each of the source/drain portions of the first semiconductor assembly, and forming a second metal contact feature on each of the source/drain portions of the second semiconductor assembly, a height of the first metal contact feature being greater than a height of the second metal contact feature.

### BACKGROUND

Due to rapid growth in the semiconductor technology, a semiconductor device including semiconductor structures in a logic region and/or semiconductor structures in a memory region is widely applied in various electronic products, such as a mobile phone, a central processing unit (CPU) in a computer, etc. In order to meet application needs, improvement in functionality and electrical performance of the semiconductor device is required.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2A to 6C are schematic views illustrating some intermediate stages of the method as depicted in FIG. 1 in accordance with some embodiments.

FIGS. 7 to 15 are schematic views each of which illustrates a semiconductor device in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “bottom,” “uppermost,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

An integrated circuit (IC) chip includes a plurality of semiconductor devices (e.g., logic devices and memory devices), which have wide applications in consumer's electrical products. In order to meet application needs, the semiconductor industry is devoted to improving device performance of the semiconductor devices. However, improvement in the device performance of the semiconductor devices may be hindered by some issues (e.g., parasitic resistance, leakage, etc.).

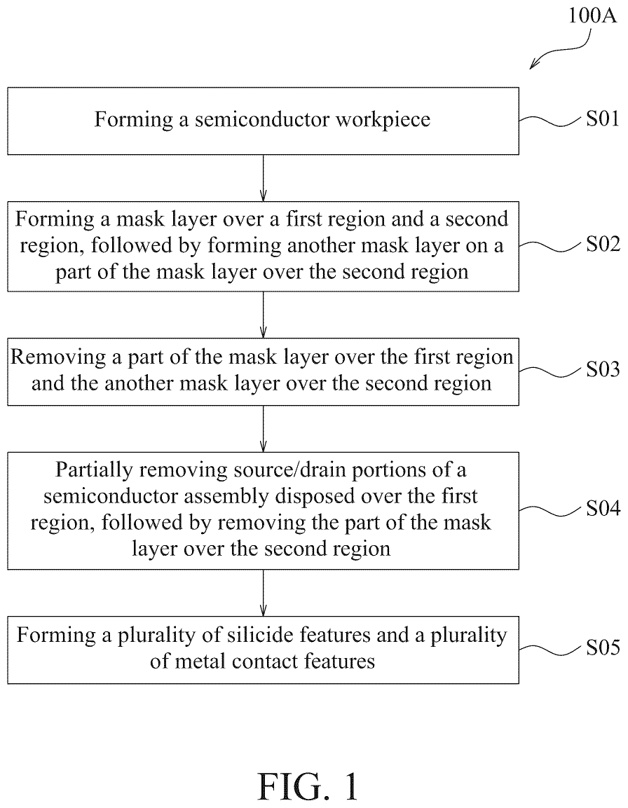

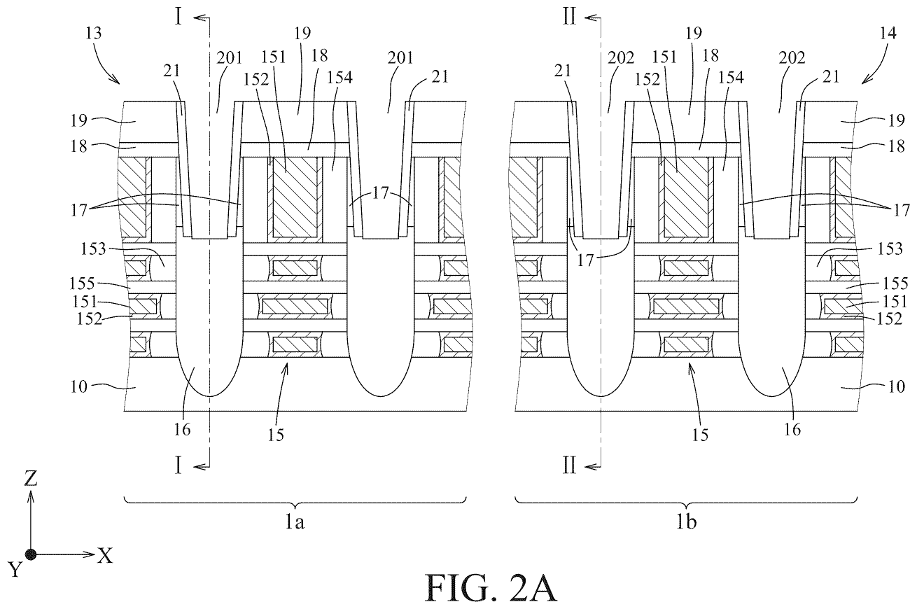

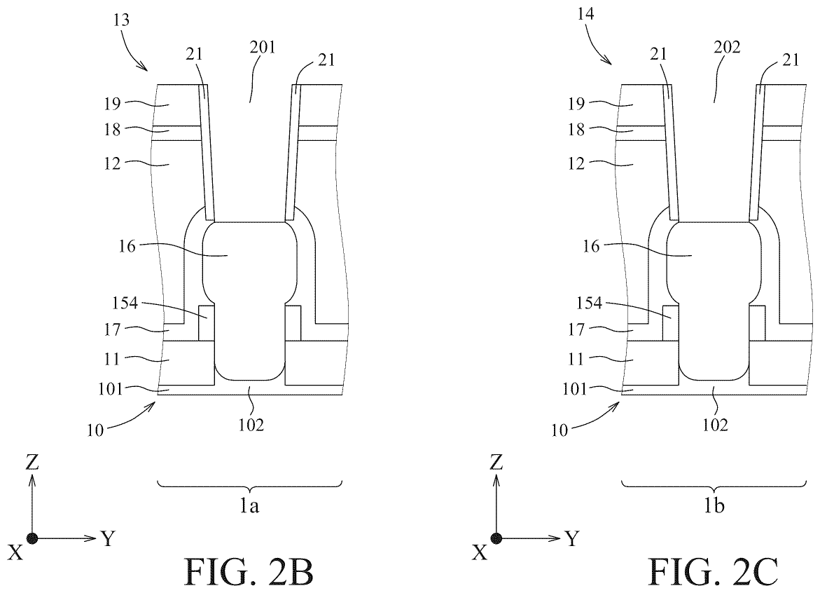

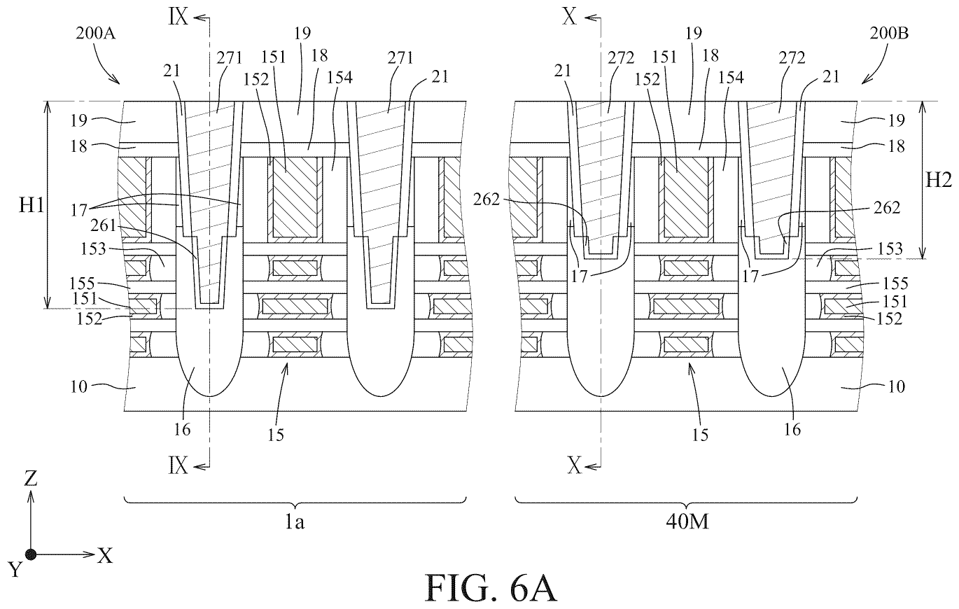

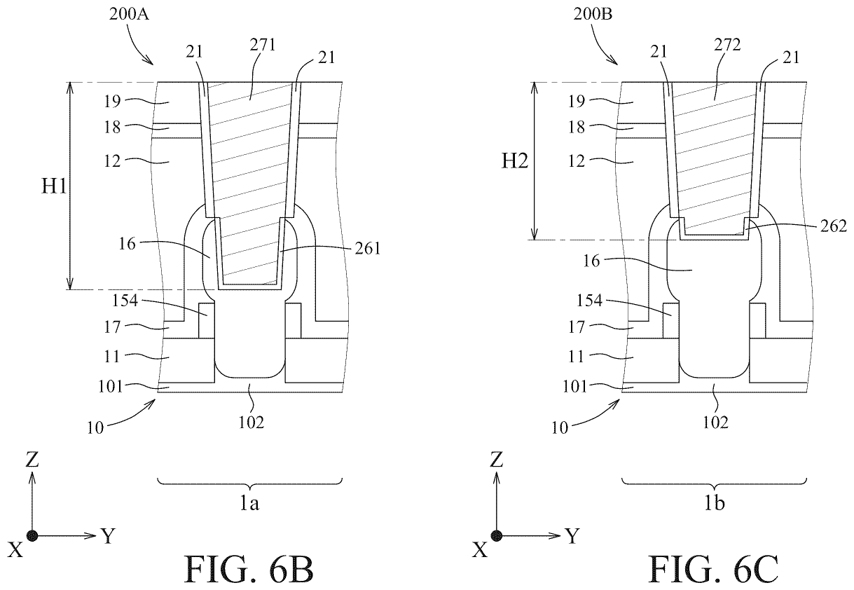

The present disclosure is directed to a semiconductor device and a method for manufacturing the same. FIG. 1 is a flow diagram illustrating a method 100A for manufacturing a semiconductor device including, for example, a first semiconductor structure 200A (see FIGS. 6A and 6B) or a second semiconductor structure 200B (see FIGS. 6A and 6C). FIGS. 2A to 5C illustrate schematic views of some intermediate stages of the method 100A. Some portions may be omitted in FIGS. 2A to 6C for the sake of brevity. Additional steps can be provided before, after or during the method 100A, and some of the steps described herein may be replaced by other steps or be eliminated.

Referring to FIG. 1 and the example illustrated in FIGS. 2A to 2C, the method 100A begins at step S01, where a semiconductor workpiece is formed. FIG. 2B illustrates a cross-sectional view taken along line I-I of FIG. 2A. FIG. 2C illustrates a cross-sectional view taken along line II-II of FIG. 2A. The semiconductor workpiece includes a semiconductor substrate 10, a plurality of isolation portions 11, a dielectric layer 12, a first semiconductor assembly 13 and a second semiconductor assembly 14.

The semiconductor substrate 10 may include, for example, but not limited to, an elemental semiconductor or a compound semiconductor. In some embodiments, the elemental semiconductor includes a single species of atoms, such as silicon or germanium in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 10 may include a multilayer compound semiconductor structure. In some embodiments, the semiconductor substrate 10 may be a semiconductor on insulator (SOI) (e.g., silicon germanium on insulator (SGOI)). The SOI substrate may be doped with a p-type dopant, for example, but not limited to, boron, aluminum, or gallium. Other suitable p-type dopant materials are within the contemplated scope of the present disclosure. Alternatively, the SOI substrate may be doped with an n-type dopant, for example, but not limited to, nitrogen, phosphorous, or arsenic. Other suitable n-type dopant materials are within the contemplated scope of the present disclosure. As shown in FIGS. 2B and 2C, in some embodiments, the semiconductor substrate 10 includes a lower portion 101 and a plurality of fin portions 102 disposed on the lower portion 101. In some embodiments, the semiconductor substrate 10 may be divided into a first region 1a for the first semiconductor structure 200A to be subsequently formed thereon, and a second region 1b for the second semiconductor structure 200B to be subsequently formed thereon.

The isolation portions 11 are disposed on the lower portion 101 of the semiconductor substrate 10. Each of the isolation portions 11 is located at two opposite sides of a corresponding one of the fin portions 102 of the semiconductor substrate 10. The two opposite sides of the corresponding one of the fin portions 102 are opposite to each other in a Y direction that is parallel to the semiconductor substrate 10. In some embodiments, the isolation portions 11 may be made of an oxide-based material (e.g., silicon oxide), a nitride-based material (e.g., silicon nitride), or a combination thereof. Other suitable materials for forming the isolation portions 11 are within the contemplated scope of the present disclosure. In some embodiments, each of the isolation portions 11 may be a portion of a shallow trench isolation (STI), a deep trench isolation (DTI), or other suitable isolation structures.

As shown in FIG. 2B, the dielectric layer 12 is disposed on the semiconductor substrate 10 and the isolation portions 11. In some embodiments, the dielectric layer 12 may include, for example, but not limited to, a dielectric oxide-based material (e.g., silicon oxide), a low-dielectric constant (k) dielectric material, an extremely low-k dielectric material, or combinations thereof. Other suitable materials for the dielectric layer 12 are within the contemplated scope of the present disclosure.

The first semiconductor assembly 13 and the second semiconductor assembly 14 are disposed on the semiconductor substrate 10. Each of the first semiconductor assembly 13 and the second semiconductor assembly 14 includes a nanosheet structure 15, a pair of source/drain portions 16, a plurality of contact etch stop portions 17, a plurality of etch stop portions 18, a pair of openings 201, 202, and a plurality of silicon nitride layer portions 21. A dielectric layer 19 is disposed on the etch stop portions 18.

The nanosheet structure 15 is disposed on the semiconductor substrate 10 in a Z direction. The Z direction is transverse to the Y direction and is normal to a bottom surface of the semiconductor substrate 10. The nanosheet structure 15 of the first semiconductor assembly 13 is spaced apart from the nanosheet structure 15 of the second semiconductor assembly 14 in an X direction transverse to the Y direction and the Z direction. In some embodiments, the X direction, the Y direction, and the Z direction are perpendicular to one another. In some embodiments, the nanosheet structure 15 includes a metal gate feature 151, a plurality of gate dielectric features 152, a plurality of inner spacers 153, a pair of gate spacers 154, and a plurality of channel features 155.

The metal gate feature 151 includes an upper gate portion disposed on the channel features 155 and a lower gate portion surrounding the channel features 155. The metal gate feature 151 may include, for example, but not limited to, metal (e.g., tungsten), metal nitride (e.g., titanium nitride or tantalum nitride), or a combination thereof. Other suitable materials for the metal gate feature 151 are within the contemplated scope of the present disclosure.

The gate dielectric features 152 cover the metal gate feature 151, while exposing an upper surface of the upper gate portion of the metal gate feature 151. In some embodiments, the gate dielectric features 152 may include, for example, but not limited to, silicon oxide, silicon nitride, silicon oxynitride, silicon carbonitride, silicon oxycarbonitride, silicon oxycarbide, a high-k material (e.g., hafnium oxide, aluminum oxide, etc.), or combinations thereof. Other suitable materials for the gate dielectric features 152 are within the contemplated scope of the present disclosure. In some embodiments, each of the gate dielectric features 152 may be formed as a multilayered structure.

Each pair of the inner spacers 153 laterally covers a corresponding one of the gate dielectric features 152. In some embodiments, the inner spacers 153 may include, for example, but not limited to, silicon oxide, silicon nitride, silicon carbide, silicon oxycarbide, silicon oxynitride, silicon carbonitride, silicon oxycarbonitride, other low-k materials, or combinations thereof. Other suitable materials for the inner spacers 153 are within the contemplated scope of the present disclosure. In some embodiments, the inner spacers 153 may have different widths due to process variations.

The gate spacers 154 respectively cover two opposite lateral surfaces of an uppermost one of the gate dielectric features 152 of the nanosheet structure 15. In some embodiments, the gate spacers 154 may include, for example, but not limited to, silicon oxide, silicon nitride, silicon oxynitride, silicon carbonitride, silicon oxycarbonitride, low-k materials, or combinations thereof. Other suitable materials for the gate spacers 154 are within the contemplated scope of the present disclosure.

The channel features 155 are disposed above the semiconductor substrate 10 and are spaced apart from one another in the Z direction. The channel features 155 are formed from semiconductor nanosheets, which may be, for example, but not limited to, silicon nanosheets. Other suitable semiconductor nanosheets for forming the channel features 155 are within the contemplated scope of the present disclosure. The channel features 155 collectively form a channel region between the source/drain portions 16. In this case, a number of the channel features 155 of the nanosheet structure 15 is 3. It should be noted that there is no particular limitation on a number of the channel features 155 of the nanosheet structure 15.

The source/drain portions 16 are disposed at two opposite sides of the nanosheet structure 15 in the X direction. In some embodiments, each of the source/drain portions 16 may include silicon boron, silicon germanium, silicon phosphide, or silicon arsenic. In some embodiments, the source/drain portions 16 of each of the first semiconductor assembly 13 and the second semiconductor assembly 14 may have an n-type conductivity or a p-type conductivity.

Each of the contact etch stop portions 17 covers a corresponding one of the gate spacers 154 and a corresponding one of the source/drain portions 16. In some embodiments, each of the contact etch stop portions 17 may include, for example, but not limited to, silicon oxide, silicon nitride, silicon oxynitride, or combinations thereof. Other suitable materials for the contact etch stop portions 17 are within the contemplated scope of the present disclosure.

The etch stop portions 18 are disposed on the dielectric layer 12, the nanosheet structure 15, and the contact etch stop portions 17. In some embodiments, the etch stop portions 18 may include, for example, but not limited to, nitride-based material (e.g., silicon nitride). Other suitable materials for the etch stop portions 18 are within the contemplated scope of the present disclosure. The etch stop portions 18 are used to prevent the metal gate feature 151 of each of the first semiconductor assembly 13 and the second semiconductor assembly 14 from being oxidized.

The dielectric layer 19 is disposed on the etch stop portions 18 opposite to the dielectric layer 12. The material for the dielectric layer 19 is the same as or similar to that for the dielectric layer 12, and details thereof are omitted for the sake of brevity.

Each of the openings 201, 202 penetrates the dielectric layer 19, an etch stop layer (not shown) for forming the etch stop portions 18, a corresponding one of a plurality of inter-layer dielectric features (not shown), a contact etch stop layer (not shown) for forming the contact etch stop portions 17, and the dielectric layer 12. In some embodiments, the openings 201 and the openings 202 may have a same depth in the Z direction measured from an upper surface of the dielectric layer 19.

Each pair of the silicon nitride layer portions 21 is disposed in a corresponding one of the openings 201, 202. The silicon nitride layer portions 21 may be referred to as silicon nitride redepositions (SNRs).

In some embodiments, each of the first semiconductor assembly 13 and the second semiconductor assembly 14 may further include a plurality of interfacial features (not shown), a plurality of first layers (not shown), and a plurality of insulator layers (not shown).

Each of the interfacial features surrounds a corresponding one of the channel features 155. In some embodiments, the interfacial features may include, for example, but not limited to, silicon oxide. Other suitable materials for the interfacial features are within the contemplated scope of the present disclosure.

Each of the first layers is disposed between the semiconductor substrate 10 and a corresponding one of the source/drain portions 16. In some embodiments, the first layers may include, for example, but not limited to, silicon.

Each of the insulator layers is disposed between a corresponding one of the first layers and a corresponding one of the source/drain portions 16. In some embodiments, the insulator layers may be made of a dielectric material, for example, but not limited to, silicon nitride, silicon oxide, silicon oxynitride, silicon carbonitride, silicon oxycarbonitride, silicon oxycarbide, a high-k material (e.g., hafnium oxide, aluminum oxide, etc.), or combinations thereof. Other suitable materials for the insulator layers are within the contemplated scope of the present disclosure. In some embodiments, each of the insulator layers may be formed as a multilayered structure. In some embodiments, the insulator layers may be referred to as flexible bottom insulators (FBIs), and may be used to shut off a leakage path in the first semiconductor structure 200A and/or the second semiconductor structure 200B.

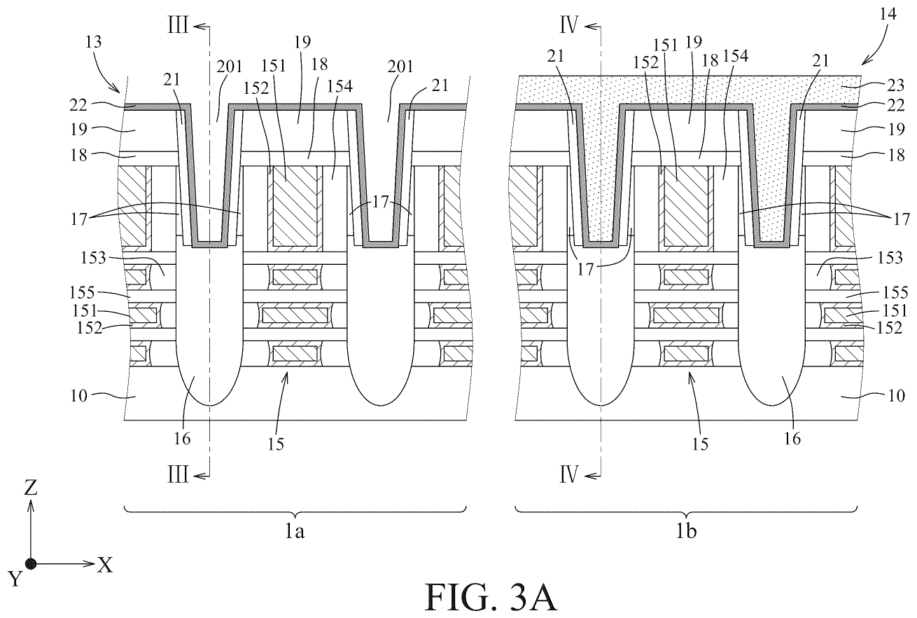

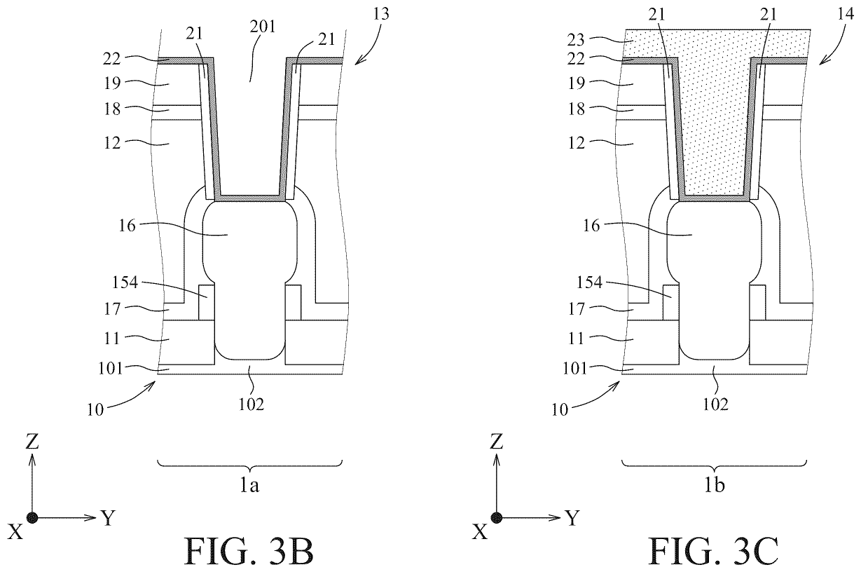

Referring to FIG. 1 and the example illustrated in FIGS. 3A to 3C, the method 100A then proceeds to step S02, where a mask layer 22 is formed on the first semiconductor assembly 13 and the second semiconductor assembly 14, followed by forming a mask layer 23 on a part of the mask layer 22 over the second region 1b. FIG. 3B illustrates a cross-sectional view taken along line III-III of FIG. 3A. FIG. 3C illustrates a cross-sectional view taken along line IV-IV of FIG. 3A. In some embodiments, the mask layer 22 may be made of a dielectric material, for example, but not limited to, silicon oxide or aluminum oxide. Other suitable materials for forming the mask layer 22 are within the contemplated scope of the present disclosure. In some embodiments, the mask layer 22 may be conformally formed on the structure shown in FIGS. 2A, 2B, and 2C by a suitable deposition process, for example, but not limited to, chemical vapor deposition (CVD) or atomic layer deposition (ALD). Other suitable deposition processes for forming the mask layer 22 are within the contemplated scope of the present disclosure. In some embodiments, the mask layer 23 may be a patterned photoresist layer. In some embodiments, the mask layer 23 may be formed by coating a photoresist layer (not shown) on the mask layer 22 over the first region 1a and the second region 1b, followed by removing a part of the photoresist layer over the first region 1a, so as to form the patterned photoresist layer (i.e., the mask layer 23) on the part of the mask layer 22 over the second region 1b.

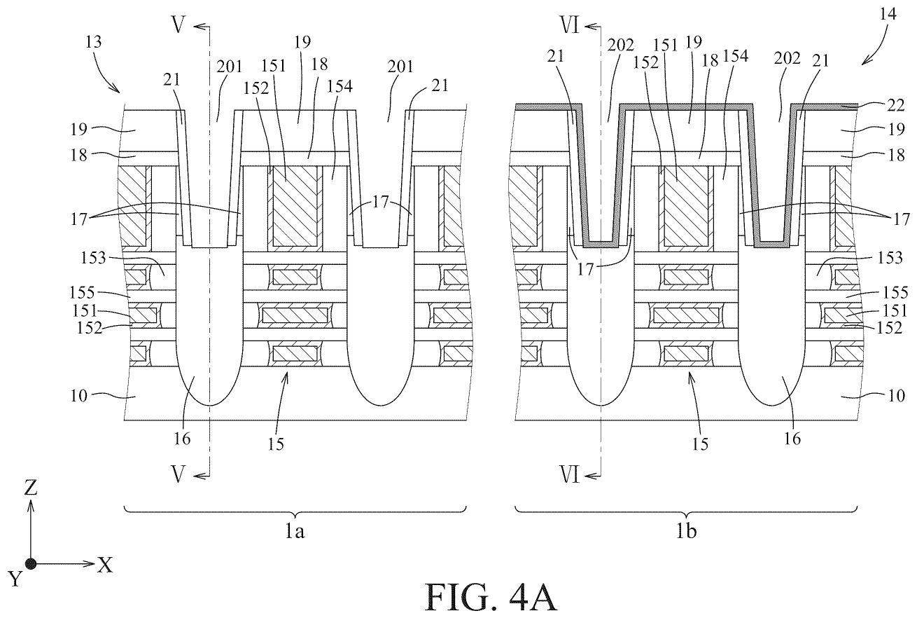

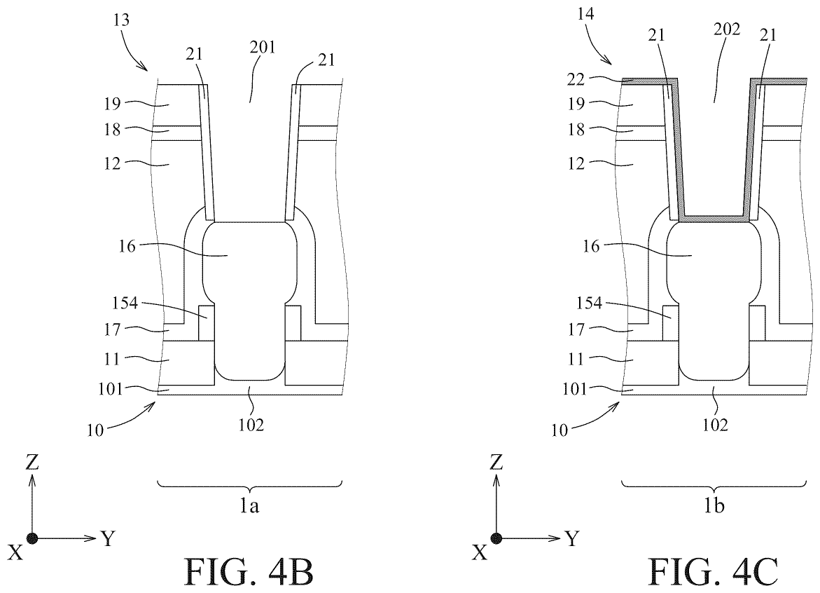

Referring to FIG. 1 and the example illustrated in FIGS. 4A to 4C, the method 100A then proceeds to step S03, where the part of the mask layer 22 over the first region 1a is removed, followed by removing the mask layer 23 over the second region 1b. FIG. 4B illustrates a cross-sectional view taken along line V-V of FIG. 4A. FIG. 4C illustrates a cross-sectional view taken along line VI-VI of FIG. 4A. In some embodiments, the part of the mask layer 22 over the first region 1a may be removed by a suitable removal process, for example, but not limited to, a dry etching process, a wet etching process, or a combination thereof. In some embodiments, the mask layer 23 over the second region 1b may be removed by a suitable removal process, for example, but not limited to, a wet etching process, an ashing process, or a combination thereof. Other suitable removal processes for removing the part of the mask layer 22 over the first region 1a and the mask layer 23 over the second region 1b are within the contemplated scope of the present disclosure.

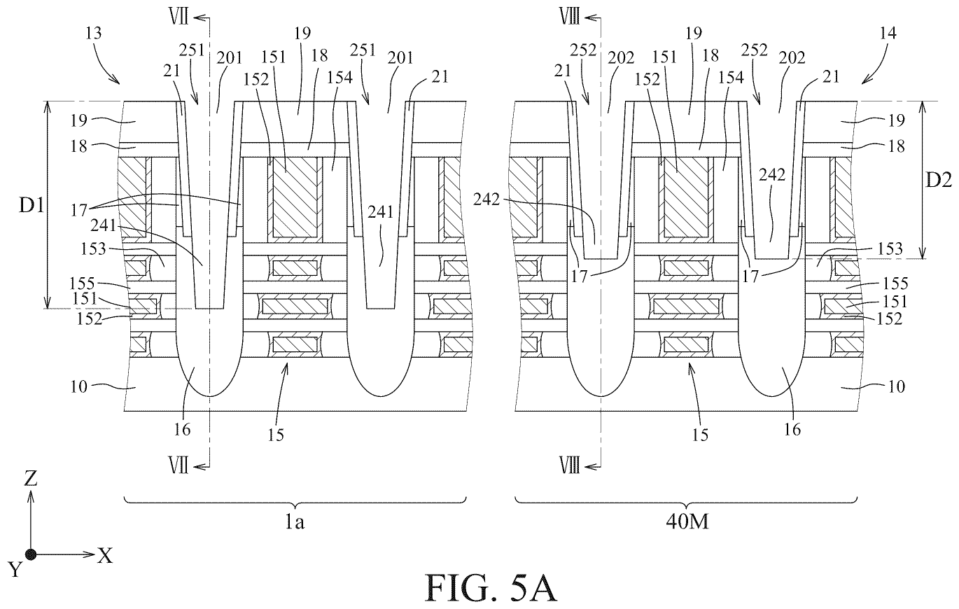

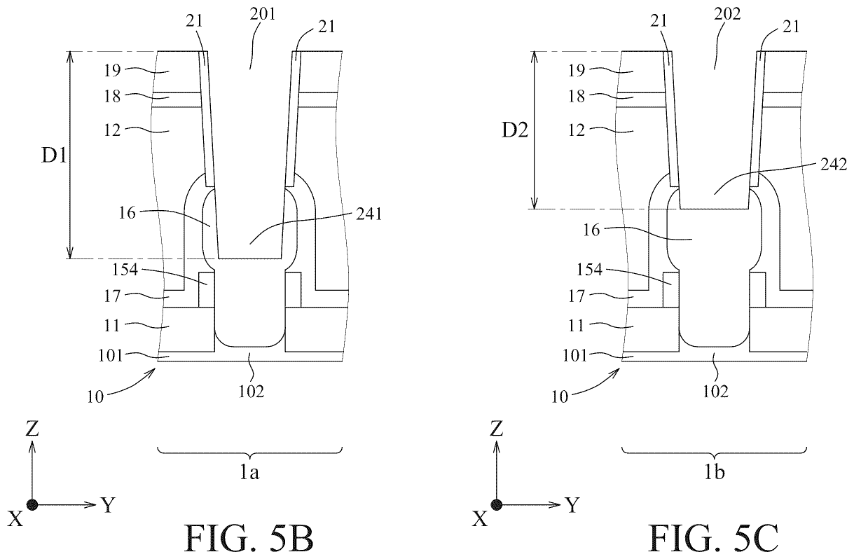

Referring to FIG. 1 and the example illustrated in FIGS. 5A to 5C, the method 100A then proceeds to step S04, where the source/drain portions 16 of the first semiconductor assembly 13 disposed over the first region 1a are partially removed, followed by removing the part of the mask layer 22 over the second region 1b. FIG. 5B illustrates a cross-sectional view taken along line VII-VII of FIG. 5A. FIG. 5C illustrates a cross-sectional view taken along line VIII-VIII of FIG. 5A. In some embodiments, the source/drain portions 16 of the first semiconductor assembly 13 disposed over the first region 1a may be removed by a suitable removal process, for example, but not limited to, an anisotropic etching process. In some embodiments, the part of the mask layer 22 over the second region 1b may be removed by a suitable removal process, which is the same as or similar to the removal process for removing the part of the mask layer 22 over the first region 1a (as described in step S03). After this step, a plurality of openings 241, 242 are formed. The openings 241 are in spatial communication with the openings 201, respectively. In some embodiments, each of the openings 241 and a corresponding one of the openings 201 may be collectively referred to as an opening structure 251 (i.e., a pair of the opening structures 251 is formed after this step). Each of the source/drain portions 16 of the first semiconductor assembly 13 is exposed from a corresponding one of the opening structures 251. The openings 242 are in spatial communication with the openings 202, respectively. In some embodiments, each of the openings 242 and a corresponding one of the openings 202 may be collectively referred to as an opening structure 252 (i.e., a pair of the opening structures 252 is formed after this step). Each of the source/drain portions 16 of the second semiconductor assembly 14 is exposed from a corresponding one of the opening structures 252. In some embodiments, each of the opening structures 251 has a depth D1 in the Z direction that is measured from the upper surface of the dielectric layer 19. In some embodiments, each of the opening structures 252 has a depth D2 in the Z direction that is measured from the upper surface of the dielectric layer 19. In some embodiments, the depth D1 is greater than the depth D2. It should be noted that when the source/drain portions 16 of the second semiconductor assembly 14 are not partially removed during the removal process of the part of the mask layer 22 over the second region 1b, the openings 242 may not be formed after this step.

Referring to FIG. 1 and the example illustrated in FIGS. 6A to 6C, the method 100A then proceeds to step S05, where a plurality of silicide features 261, 262 and a plurality of metal contact features 271, 272 are formed. The silicide features 261 are formed in the openings 241 (see FIGS. 5A and 5B), respectively. The silicide features 262 are formed in the openings 242 (see FIGS. 5A and 5C), respectively. In some embodiments, the silicide features 261, 262 include metal silicide, which may include, for example, but not limited to, titanium silicide. Other suitable materials for forming the silicide features 261, 262 are within the contemplated scope of the present disclosure. The metal contact features 271 are respectively formed on the silicide features 261, and respectively fill the opening structures 251 (see FIGS. 5A and 5B). The metal contact features 272 are respectively formed on the silicide features 262, and respectively fill the opening structures 252 (see FIGS. 5A and 5C). In some embodiments, the metal contact features 271, 272 may include, for example, but not limited to, cobalt, tungsten, ruthenium, molybdenum, or combinations thereof. Other suitable materials for forming the metal contact features 271, 272 are within the contemplated scope of the present disclosure. In some embodiments, the metal contact features 271, 272 may be formed by depositing a conductive material layer for forming the metal contact features 271, 272 such that the conductive material layer fills the opening structures 251, 252, followed by conducting a planarization process (for example, but not limited to, chemical mechanical polishing (CMP) or other suitable planarization processes) to remove an excess portion of the conductive material layer, so as to obtain the metal contact features 271, 272.

After step S05, the first semiconductor structure 200A (see FIGS. 6A and 6B) and the second semiconductor structure 200B (see FIGS. 6A and 6C) are obtained. In some embodiments, the first semiconductor structure 200A is used as a logic structure, and the first region 1a is referred to as a logic region. In some embodiments, the second semiconductor structure 200B is used as a memory structure (e.g., a static random-access memory (SRAM)), and the second region 1b is referred to as a memory region.

In some embodiments, each of the metal contact features 271 of the first semiconductor structure 200A has a height H1 in the Z direction which is measured from the upper surface of the dielectric layer 19 to a lower surface of a corresponding one of the silicide features 261, and which ranges from about 15 nm to about 100 nm. In some embodiments, each of the metal contact features 272 of the second semiconductor structure 200B has a height H2 in the Z direction which is measured from the upper surface of the dielectric layer 19 to a lower surface of a corresponding one of the silicide features 262, and which ranges from about 12 nm to about 98 nm. In some embodiments, a difference between the height H1 and the height H2 may range from about 2 nm to about 50 nm. In the first semiconductor structure 200A (e.g., used as a logic structure), due to a relatively large height of each of the metal contact features 271, a contact area between the each of the metal contact features 271 and a corresponding one of the source/drain portions 16 may increase, which is conducive to reducing a parasitic resistance of the first semiconductor structure 200A, and to further improve an electrical performance (e.g., a direct current (DC) performance) thereof. In the second semiconductor structure 200B (e.g., used as a static random-access memory (SRAM) structure), the height H2 of each of the metal contact features 272 is relatively small, which is conducive to preventing a leakage between the metal gate feature 151 and the metal contact features 272. In some embodiments, in the first semiconductor structure 200A, a lower surface of the metal contact feature 271 may be located at a level lower than that of a lower surface of an intermediate one of the channel features 155. In some embodiments, in the second semiconductor structure 200B, a lower surface of the metal contact feature 272 may be located at a level higher than that of a lower surface of an intermediate one of the channel features 155.

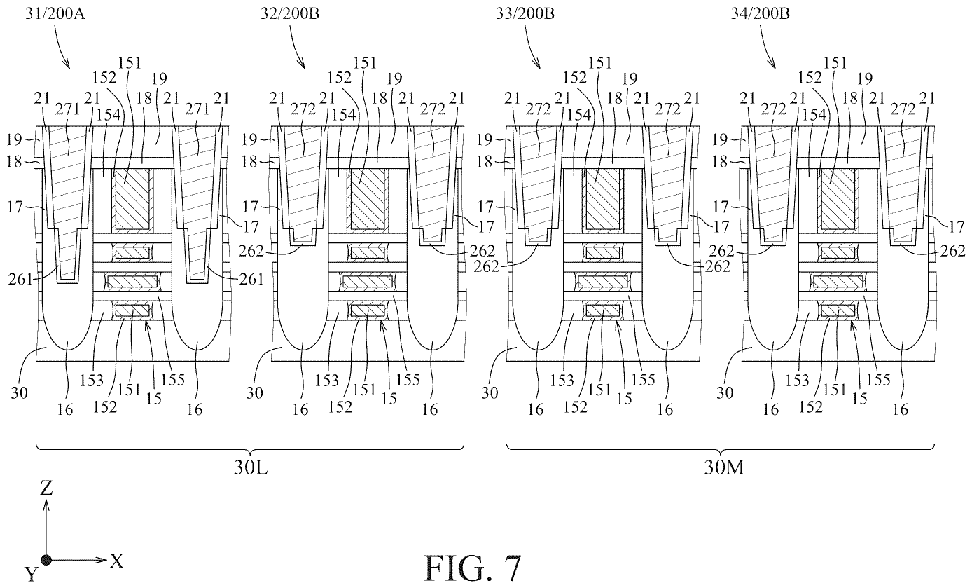

As shown in FIG. 7, in some embodiments, a semiconductor device includes a semiconductor substrate 30, a first n-type metal-oxide-semiconductor field effect transistor (NMOSFET) 31, a first p-type metal-oxide-semiconductor field effect transistor (PMOSFET) 32, a second NMOSFET 33, and a second PMOSFET 34. The semiconductor substrate 30 may be the same as or similar to the semiconductor substrate 10 (see, for example, FIG. 2A) and includes a logic region 30L and a memory region 30M (e.g., the SRAM region), where the first NMOSFET 31 and the first PMOSFET 32 are located in the logic region 30L, and the second NMOSFET 33 and the second PMOSFET 34 are located in the memory region 30M. In some embodiments, the first semiconductor structure 200A shown in FIG. 6A is used as the first NMOSFET 31, and the second semiconductor structure 200B shown in FIG. 6A is used as each of the first PMOSFET 32, the second NMOSFET 33, and the second PMOSFET 34. In some embodiments, the second semiconductor structure 200B shown in FIG. 6A and used as each of the first PMOSFET 32 and the second PMOSFET 34 is advantageous for generating sufficient strain to the channel features 155.

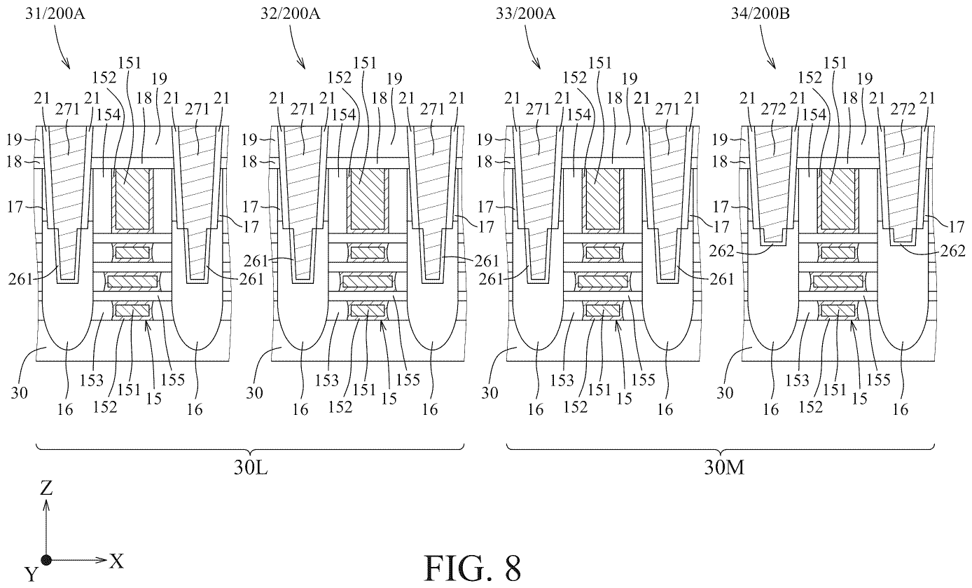

As shown in FIG. 8, in some embodiments, the first semiconductor structure 200A shown in FIG. 6A is used as each of the first NMOSFET 31, the first PMOSFET 32, and the second NMOSFET 33, and the second semiconductor structure 200B shown in FIG. 6A is used as the second PMOSFET 34.

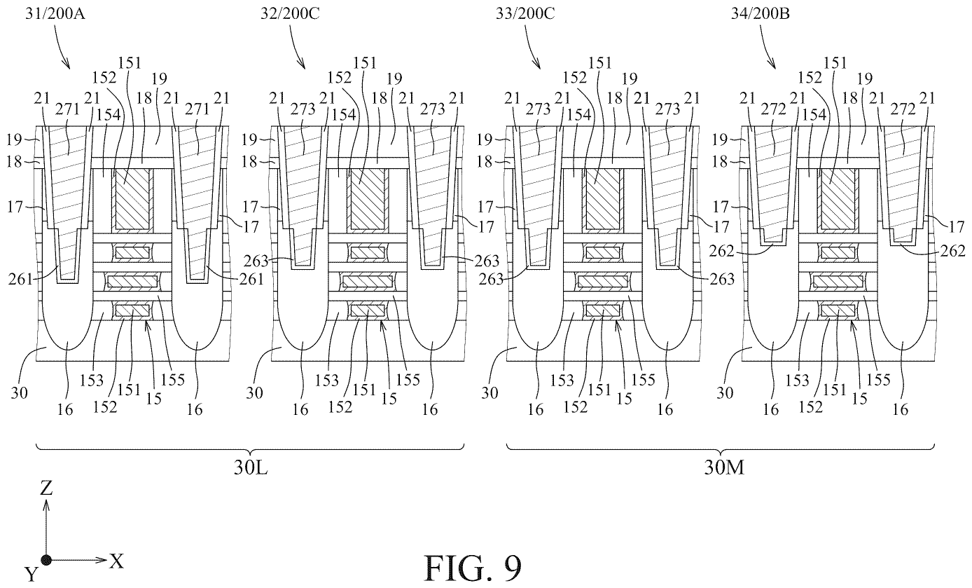

As shown in FIG. 9, in some embodiments, the first semiconductor structure 200A shown in FIG. 6A is used as the first NMOSFET 31, and the second semiconductor structure 200B shown in FIG. 6A is used as the second PMOSFET 34. In addition, a third semiconductor structure 200C is included and used as each of the first PMOSFET 32 and the second NMOSFET 33. In some embodiments, a height of each of metal contact features 273 of the third semiconductor structure 200C is between the height H1 of each of the metal contact features 271 of the first semiconductor structure 200A and the height H2 of each of the metal contact features 272 of the second semiconductor structure 200B.

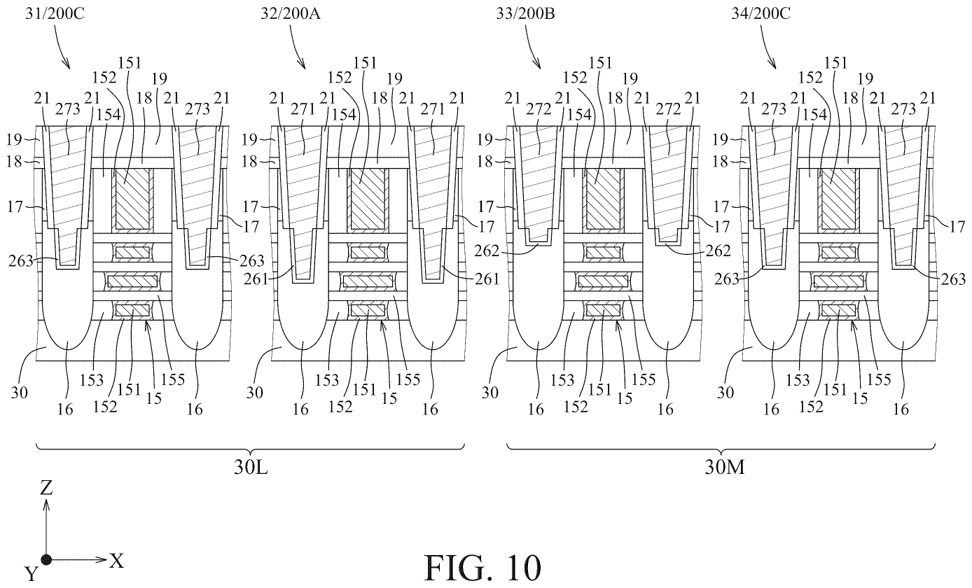

As shown in FIG. 10, in some embodiments, the first semiconductor structure 200A shown in FIG. 6A is used as the first PMOSFET 32, the second semiconductor structure 200B shown in FIG. 6A is used as the second NMOSFET 33, and the third semiconductor structure 200C is used as each of the first NMOSFET 31 and the second PMOSFET 34.

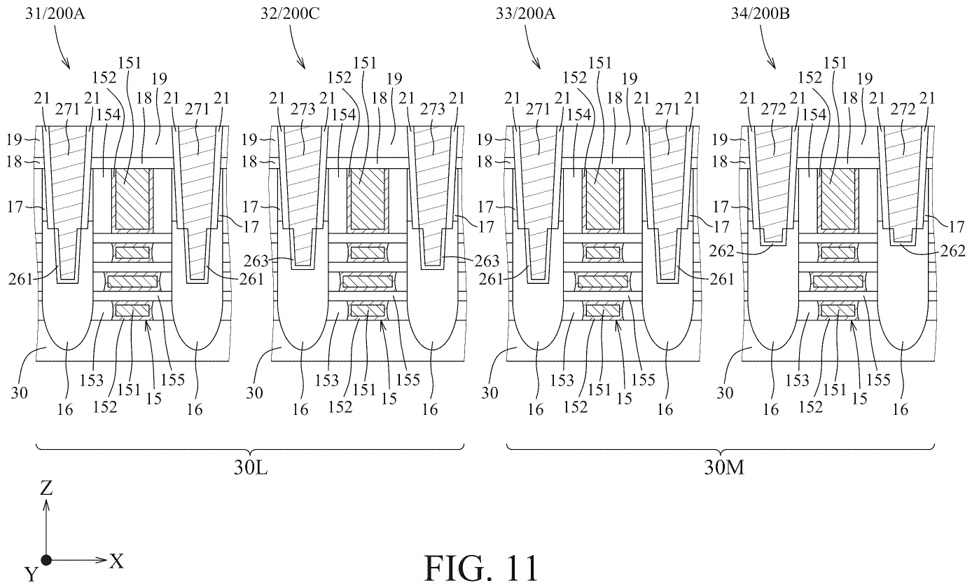

As shown in FIG. 11, in some embodiments, the first semiconductor structure 200A shown in FIG. 6A is used as each of the first NMOSFET 31 and the second NMOSFET 33, the second semiconductor structure 200B shown in FIG. 6A is used as the second PMOSFET 34, and the third semiconductor structure 200C is used as the first PMOSFET 32.

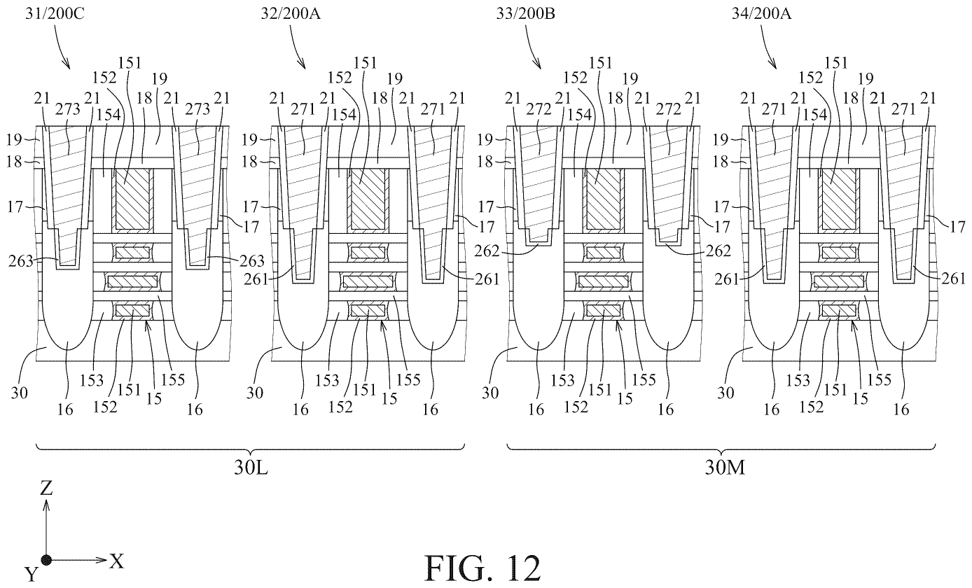

As shown in FIG. 12, in some embodiments, the first semiconductor structure 200A shown in FIG. 6A is used as each of the first PMOSFET 32 and the second PMOSFET 34, the second semiconductor structure 200B shown in FIG. 6A is used as the second NMOSFET 33, and the third semiconductor structure 200C is used as the first NMOSFET 31.

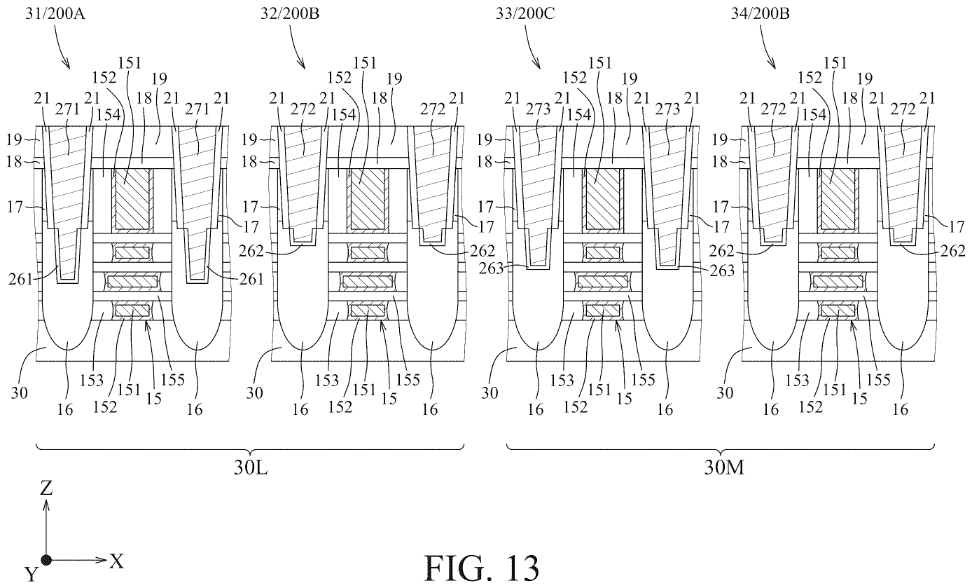

As shown in FIG. 13, in some embodiments, the first semiconductor structure 200A shown in FIG. 6A is used as the first NMOSFET 31, the second semiconductor structure 200B shown in FIG. 6A is used as each of the first PMOSFET 32 and the second PMOSFET 34, and the third semiconductor structure 200C is used as the second NMOSFET 33.

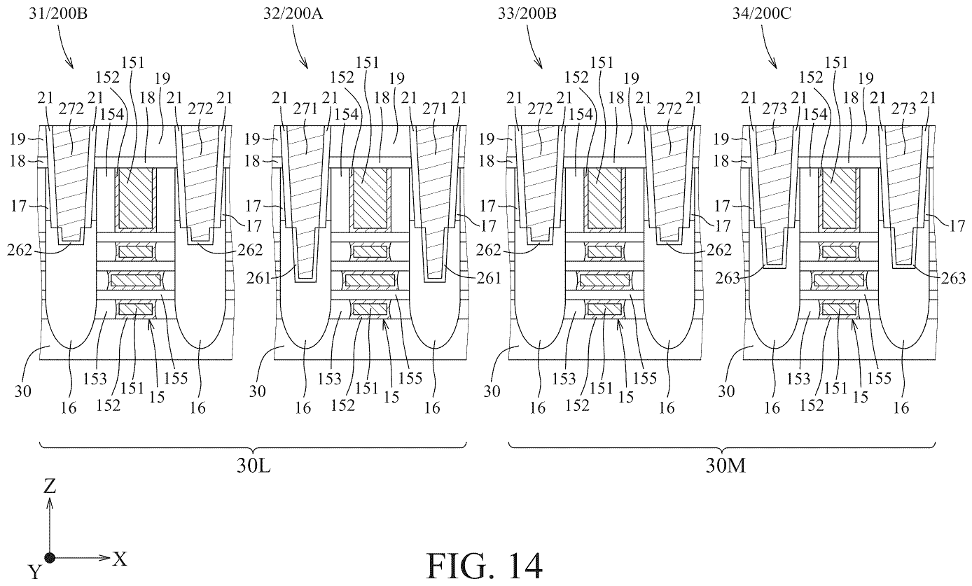

As shown in FIG. 14, in some embodiments, the first semiconductor structure 200A shown in FIG. 6A is used as the first PMOSFET 32, the second semiconductor structure 200B shown in FIG. 6A is used as each of the first NMOSFET 31 and the second NMOSFET 33, and the third semiconductor structure 200C is used as the second PMOSFET 34.

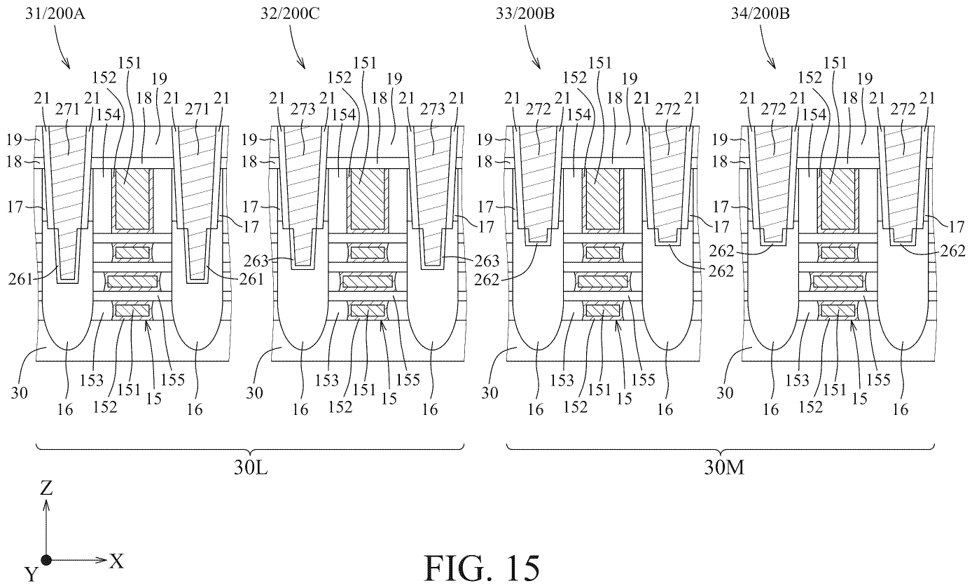

As shown in FIG. 15, in some embodiments, the first semiconductor structure 200A shown in FIG. 6A is used as the first NMOSFET 31, the second semiconductor structure 200B shown in FIG. 6A is used as the second NMOSFET 33 and the second PMOSFET 34, and the third semiconductor structure 200C is used as the first PMOSFET 32.

In a semiconductor structure of this disclosure, by increasing a height of a metal contact feature, a contact area between the metal contact feature and a source/drain portion in contact with of the metal contact feature may be increased, which is conducive to reducing a parasitic resistance in the semiconductor structure, and to further improve an electrical performance (e.g., a direct current (DC) performance) thereof.

In accordance with some embodiments of the present disclosure, a method for manufacturing a semiconductor device includes: forming a first semiconductor assembly and a second semiconductor assembly on a semiconductor substrate, each of the first semiconductor assembly and the second semiconductor assembly including a pair of source/drain portions that are spaced apart from each other; forming a first mask layer to selectively cover the pair of source/drain portions of the second semiconductor assembly, so as to expose the pair of source/drain portions of the first semiconductor assembly; removing a part of each of the pair of source/drain portions of the first semiconductor assembly; removing the first mask layer so as to expose the pair of source/drain portions of the second semiconductor assembly; and forming a first metal contact feature on a remaining part of each of the pair of source/drain portions of the first semiconductor assembly, and forming a second metal contact feature on each of the pair of source/drain portions of the second semiconductor assembly. The first metal contact feature has a first height. The second metal contact feature has a second height that is less than the first height of the first metal contact feature.

In accordance with some embodiments of the present disclosure, the pair of source/drain portions of the second semiconductor assembly is selectively covered by: forming the first mask layer that includes a first part and a second part, wherein the first part of the first mask layer covers the pair of source/drain portions of the first semiconductor assembly and the second part of the first mask layer covers the pair of source/drain portions of the second semiconductor assembly; forming a second mask layer on the second part of the first mask layer; and removing the first part of the first mask layer and the second mask layer.

In accordance with some embodiments of the present disclosure, the first part and the second part of the first mask layer are removed separately.

In accordance with some embodiments of the present disclosure, the second mask layer is removed after removing the first part of the first mask layer.

In accordance with some embodiments of the present disclosure, the first height of the first metal contact feature is greater than the second height of the second metal contact feature by a value ranging from about 2 nm to about 50 nm.

In accordance with some embodiments of the present disclosure, the first mask layer includes silicon oxide, aluminum oxide, or a combination thereof.

In accordance with some embodiments of the present disclosure, the first mask layer is formed by chemical vapor deposition or atomic layer deposition.

In accordance with some embodiments of the present disclosure, the second mask layer includes photoresist.

In accordance with some embodiments of the present disclosure, the part of each of the pair of source/drain portions of the first semiconductor assembly is removed by an anisotropic etching process.

In accordance with some embodiments of the present disclosure, a method for manufacturing a semiconductor device includes: forming a first semiconductor assembly and a second semiconductor assembly on a semiconductor substrate in a first direction normal to the semiconductor substrate, each of the first semiconductor assembly and the second semiconductor assembly including a pair of source/drain portions that are spaced apart from each other in a second direction transverse to the first direction; forming a patterned dielectric layer on the first semiconductor assembly and the second semiconductor assembly, the patterned dielectric layer being formed with a pair of first openings that respectively expose the pair of source/drain portions of the first semiconductor assembly, and a pair of second openings that respectively expose the pair of source/drain portions of the second semiconductor assembly; forming a first mask layer that includes a first part and a second part, the first part being formed in the pair of first openings and on the pair of source/drain portions of the first semiconductor assembly, the second part being formed in the pair of second openings and on the pair of source/drain portions of the second semiconductor assembly; forming a second mask layer on the second part of the first mask layer; removing the first part of the first mask layer and the second mask layer so as to expose the pair of source/drain portions of the first semiconductor assembly through the pair of first openings, respectively; removing a part of each of the pair of source/drain portions of the first semiconductor assembly; removing the second part of the first mask layer to expose the pair of source/drain portions of the second semiconductor assembly through the pair of second openings, respectively; and forming a first metal contact feature on a remaining part of each of the pair of source/drain portions of the first semiconductor assembly, and forming a second metal contact feature on each of the pair of source/drain portions of the second semiconductor assembly. The first metal contact feature has a first height. The second metal contact feature has a second height that is less than the first height of the first metal contact feature.

In accordance with some embodiments of the present disclosure, each of the first semiconductor assembly and the second semiconductor assembly further includes a plurality of channel features disposed between the pair of source/drain portions in the second direction and spaced apart from one another in the first direction. A lower surface of the first metal contact feature is located at a level lower than a level of a bottom surface of an intermediate one of the plurality of channel features of the first semiconductor assembly.

In accordance with some embodiments of the present disclosure, a lower surface of the second metal contact feature is located at a level higher than a level of a bottom surface of an intermediate one of the plurality of channel features of the second semiconductor assembly.

In accordance with some embodiments of the present disclosure, a pair of third openings are formed after the part of each of the pair of source/drain portions of the first semiconductor assembly is removed. The pair of third openings is in spatial communication with the pair of first openings and extends into the pair of source/drain portions of the first semiconductor assembly, respectively.

In accordance with some embodiments of the present disclosure, a semiconductor device includes a semiconductor substrate, a first semiconductor structure, a second semiconductor structure, a first metal contact feature, and a second metal contact feature. The first semiconductor structure and the second semiconductor structure are disposed on the semiconductor substrate. Each of the first semiconductor structure and the second semiconductor structure includes a pair of source/drain portions that are spaced apart from each other. The first metal contact feature is disposed on each of the pair of source/drain portions of the first semiconductor structure. The second metal contact feature is disposed on each of the pair of source/drain portions of the second semiconductor structure. The first metal contact feature has a first height. The second metal contact feature has a second height that is less than the first height of the first metal contact feature.

In accordance with some embodiments of the present disclosure, the first height is greater than the second height by a value ranging from 2 nm to 50 nm.

In accordance with some embodiments of the present disclosure, the first metal contact feature includes a lower portion extending into the each of the pair of source/drain portions of the first semiconductor structure, and an upper portion disposed on the lower portion.

In accordance with some embodiments of the present disclosure, the second metal contact feature includes a lower portion disposed in the each of the pair of source/drain portions of the second semiconductor structure and an upper portion disposed on the lower portion of the second metal contact feature. A height of the lower portion of the first metal contact feature is greater than a height of the lower portion of the second metal contact feature.

In accordance with some embodiments of the present disclosure, the semiconductor device further includes a first silicide feature covering the lower portion of the first metal contact feature and a second silicide feature covering the lower portion of the second metal contact feature.

In accordance with some embodiments of the present disclosure, the semiconductor device further includes a dielectric layer disposed on the first semiconductor structure and the second semiconductor structure. The first metal contact feature extends from an upper surface of the dielectric layer into the each of the pair of source/drain portions of the first semiconductor structure. The first height of the first metal contact feature ranges from about 15 nm to about 100 nm.

In accordance with some embodiments of the present disclosure, the semiconductor device further includes a dielectric layer disposed on the first semiconductor structure and the second semiconductor structure. The second metal contact feature extends from an upper surface of the dielectric layer into the each of the pair of source/drain portion of the second semiconductor structure. The second height of the second metal contact feature ranges from about 12 nm to about 98 nm.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a first semiconductor assembly and a second semiconductor assembly on a semiconductor substrate, each of the first semiconductor assembly and the second semiconductor assembly including a pair of source/drain portions that are spaced apart from each other;
forming a first mask layer to selectively cover the pair of source/drain portions of the second semiconductor assembly, so as to expose the pair of source/drain portions of the first semiconductor assembly;
removing a part of each of the pair of source/drain portions of the first semiconductor assembly;
removing the first mask layer so as to expose the pair of source/drain portions of the second semiconductor assembly; and
forming a first metal contact feature on a remaining part of each of the pair of source/drain portions of the first semiconductor assembly, and forming a second metal contact feature on each of the pair of source/drain portions of the second semiconductor assembly, the first metal contact feature having a first height, the second metal contact feature having a second height that is less than the first height of the first metal contact feature.

2. The method as claimed in claim 1, wherein the pair of source/drain portions of the second semiconductor assembly is selectively covered by:
forming the first mask layer that includes a first part and a second part, wherein the first part of the first mask layer covers the pair of source/drain portions of the first semiconductor assembly and the second part of the first mask layer covers the pair of source/drain portions of the second semiconductor assembly;
forming a second mask layer on the second part of the first mask layer; and
removing the first part of the first mask layer and the second mask layer.

3. The method as claimed in claim 2, wherein the first part and the second part of the first mask layer are removed separately.

4. The method as claimed in claim 2, wherein the second mask layer is removed after removing the first part of the first mask layer.

5. The method as claimed in claim 1, wherein the first height of the first metal contact feature is greater than the second height of the second metal contact feature by a value ranging from 2 nm to 50 nm.

6. The method as claimed in claim 1, wherein the first mask layer includes silicon oxide, aluminum oxide, or a combination thereof.

7. The method as claimed in claim 1, wherein the first mask layer is formed by chemical vapor deposition or atomic layer deposition.

8. The method as claimed in claim 1, wherein the second mask layer includes photoresist.

9. The method as claimed in claim 1, wherein the part of each of the pair of source/drain portions of the first semiconductor assembly is removed by an anisotropic etching process.

10. A method for manufacturing a semiconductor device, comprising:
forming a first semiconductor assembly and a second semiconductor assembly on a semiconductor substrate in a first direction normal to the semiconductor substrate, each of the first semiconductor assembly and the second semiconductor assembly including a pair of source/drain portions that are spaced apart from each other in a second direction transverse to the first direction;
forming a patterned dielectric layer on the first semiconductor assembly and the second semiconductor assembly, the patterned dielectric layer being formed with a pair of first openings that respectively expose the pair of source/drain portions of the first semiconductor assembly, and a pair of second openings that respectively expose the pair of source/drain portions of the second semiconductor assembly;
forming a first mask layer that includes a first part and a second part, the first part being formed in the pair of first openings and on the pair of source/drain portions of the first semiconductor assembly, the second part being formed in the pair of second openings and on the pair of source/drain portions of the second semiconductor assembly;
forming a second mask layer on the second part of the first mask layer;
removing the first part of the first mask layer and the second mask layer so as to expose the pair of source/drain portions of the first semiconductor assembly through the pair of first openings, respectively;
removing a part of each of the pair of source/drain portions of the first semiconductor assembly;
removing the second part of the first mask layer to expose the pair of source/drain portions of the second semiconductor assembly through the pair of second openings, respectively; and
forming a first metal contact feature on a remaining part of each of the pair of source/drain portions of the first semiconductor assembly, and forming a second metal contact feature on each of the pair of source/drain portions of the second semiconductor assembly, the first metal contact feature having a first height, the second metal contact feature having a second height that is less than the first height of the first metal contact feature.

11. The method as claimed in claim 10, wherein each of the first semiconductor assembly and the second semiconductor assembly further includes a plurality of channel features disposed between the pair of source/drain portions in the second direction and spaced apart from one another in the first direction, a lower surface of the first metal contact feature being located at a level lower than a level of a bottom surface of an intermediate one of the plurality of channel features of the first semiconductor assembly.

12. The method as claimed in claim 11, wherein a lower surface of the second metal contact feature is located at a level higher than a level of a bottom surface of an intermediate one of the plurality of channel features of the second semiconductor assembly.

13. The method as claimed in claim 10, wherein a pair of third openings are formed after the part of each of the pair of source/drain portions of the first semiconductor assembly is removed, the pair of third openings being in spatial communication with the pair of first openings and extending into the pair of source/drain portions of the first semiconductor assembly, respectively.

14. A semiconductor device, comprising:
a semiconductor substrate;
a first semiconductor structure and a second semiconductor structure disposed on the semiconductor substrate, each of the first semiconductor structure and the second semiconductor structure including a pair of source/drain portions that are spaced apart from each other; and
a first metal contact feature disposed on each of the pair of source/drain portions of the first semiconductor structure, and a second metal contact feature disposed on each of the pair of source/drain portions of the second semiconductor structure, the first metal contact feature having a first height, the second metal contact feature having a second height that is less than the first height of the first metal contact feature.

15. The semiconductor device as claimed in claim 14, wherein the first height i greater than the second height by a value ranging from 2 nm to 50 nm.

16. The semiconductor device as claimed in claim 14, wherein the first metal contact feature includes a lower portion extending into the each of the pair of source/drain portions of the first semiconductor structure, and an upper portion disposed on the lower portion.

17. The semiconductor device as claimed in claim 16, wherein the second metal contact feature includes a lower portion disposed in the each of the pair of source/drain portions of the second semiconductor structure and an upper portion disposed on the lower portion of the second metal contact feature, a height of the lower portion of the first metal contact feature being greater than a height of the lower portion of the second metal contact feature.

18. The semiconductor device as claimed in claim 17, further comprising a first silicide feature covering the lower portion of the first metal contact feature and a second silicide feature covering the lower portion of the second metal contact feature.

19. The semiconductor device as claimed in claim 14, further comprising a dielectric layer disposed on the first semiconductor structure and the second semiconductor structure, the first metal contact feature extending from an upper surface of the dielectric layer into the each of the pair of source/drain portions of the first semiconductor structure, the first height of the first metal contact feature ranging from 15 nm to 100 nm.

20. The semiconductor device as claimed in claim 14, further comprising a dielectric layer disposed on the first semiconductor structure and the second semiconductor structure, the second metal contact feature extending from an upper surface of the dielectric layer into the each of the pair of source/drain portions of the second semiconductor structure, the second height of the second metal contact feature ranging from 12 nm to 98 nm.
